(19) United States
(12) Patent Application Publication
(10) Pub. No.: US 2003/0039103 A1
(43) Pub. Date: Feb. 27, 2003

(54) Modular base unit for car appliances

(76) Inventor: Ta-Chin Wang, Tainan (TW)

Correspondence Address: THORP REED & ARMSTRONG, LLP, ONE OXFORD CENTRE, 301 GRANT STREET, 14TH FLOOR, PITTSBURGH, PA, 15219-1425, US

(21) Appl. No.: 10/266,655

(22) Filed: Oct. 8, 2002

Related U.S. Application Data
(63) Continuation-in-part of application No. 09/934,044, filed on Aug. 21, 2001.

(51) Int. Cl. H05K 7/00

(52) U.S. Cl. 361/728

(57) ABSTRACT

A modular base unit optionally cooperates with various modular car appliances, such as car air pumps or portable lamps. The base unit includes of a case for receiving a battery fitted therein or receiving a car plug collected therein, and a connecting portion corresponding to a socket defined in the car appliance. When the base unit is detachably connected with the car appliance, the car appliance is electrically connected with a power supply via the base unit. Whereby the modular car appliances occupy a small volume in a storage space within a car, and the expenditure of both users and manufacturers are reduced because of the modularity.

The present invention relates to a Continuation-In-part Application of the Applicant's U.S. Ser. No. 09/934,044, filed on Aug. 21, 2001.

### BACKGROUND OF THE INVENTION

1. Field of the Invention

2. Description of Related Art

Conventional car appliances, such as various air pumps and portable lamps, are normally integrated. Each one of the car appliances has a base unit integrally connected with a main body thereof, therefore when more than one of the car appliances are collected together in a storage space within a car, the duplicated base units of the car appliances must occupy more storage space than only one base unit.

If a user has more than one conventional car appliance, each of which has an integrated base unit, the total expenditure of buying these different car appliances is excessive.

Furthermore, the production cost of the conventional integrated car appliances is uneconomic.

Therefore, it is an objective of the invention to provide a modular base unit for optionally cooperating with modular car appliances to mitigate and/or obviate the aforementioned problems.

### SUMMARY OF THE INVENTION

The main object of the present invention is to provide a modular base unit to optionally cooperate with various modular car appliances so as to reduce sizes of the car appliances. Therefore, the car appliances efficiently occupy a small volume so as to save the storage space within the car, the expenditure of buying various modular car appliances and a modular base is economic for a user, and the production cost of the modular car appliances and the modular base is also accordingly low.

Other objects, advantages and novel features of the invention will become more apparent from the following detailed description when taken in conjunction with the accompanying drawings.

### BRIEF DESCRIPTION OF THE DRAWINGS

FIG. 1 is an exploded perspective view of a first embodiment of a modular base unit in accordance with the invention;

FIG. 2 is an exploded perspective view of a second embodiment of the modular base unit in accordance with the invention;

FIG. 3 is an enlarged side plan view of the case and the cover plate of the modular base unit in FIG. 1;

FIG. 4 is a perspective view of a first application embodiment of the modular base unit in accordance with the invention;

FIG. 5 is a perspective view of a second application embodiment of the modular base unit in accordance with the invention;

FIG. 6 is a plan view of a third application embodiment of the modular base unit in accordance with the invention;

FIG. 7 is a plan view of a fourth application embodiment of the modular base unit in accordance with the invention; and

FIG. 8 is a perspective view of the modular base unit of the invention in cooperation with a charger.

### DETAILED DESCRIPTION OF THE PREFERRED EMBODIMENT

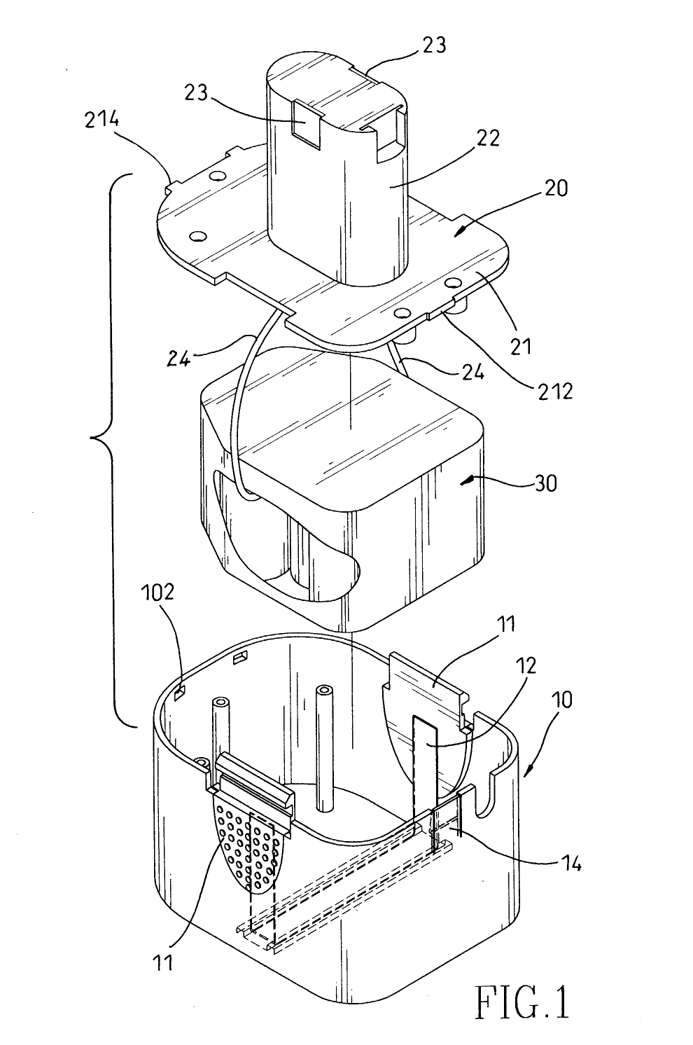

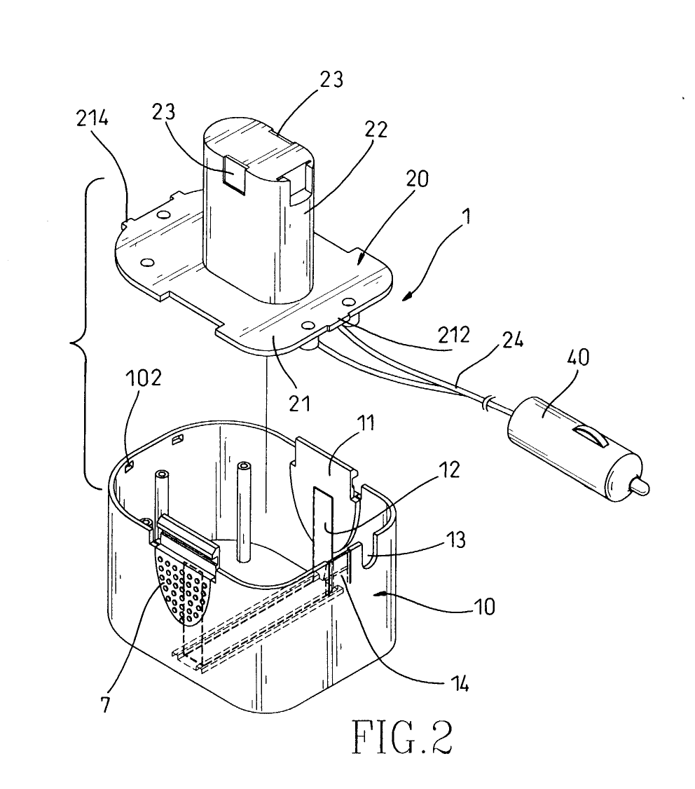

As shown in FIGS. 1 and 2, the present invention relates to a modular base unit (1) for optionally cooperating with various modular car appliances, which are designed to respectively correspond to the base unit (1). The modular base unit (1) particularly comprises a case (10) and a connecting seat (20).

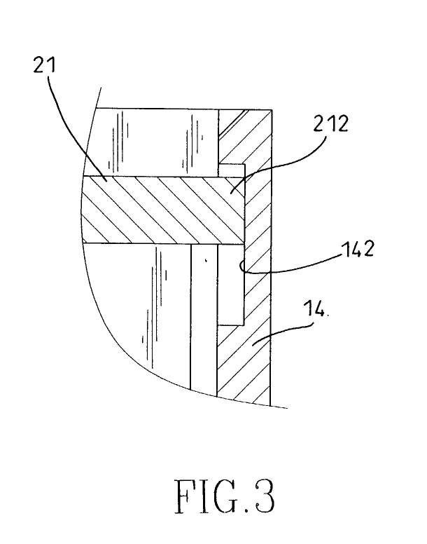

The case (10) is defined with a receiving space, which is intended to receive a battery (30) fitted therein as shown in FIG. 1, or to receive a car plug (40) collected therein as shown in FIG. 2. The battery (30) is optionally a rechargeable or non-chargeable battery. The car plug (40) corresponds to a power supply car plug jack generally provided in a normal car. Two fasteners (11) are respectively provided at two opposite inner sides of the case (10) and fixed in the case (10) by an elastic member (12). With reference to FIGS. 1 to 3, the connecting portion (20) includes a cover plate (21) detachably fixed with the case (10) in an opening of the receiving space, and a connector (22) integrally formed on the cover plate (21). The cover plate (21) is detachably fixed on the case (10) by means of lock joints or screws. In practice, two tabs (214) are formed on one end of the cover plate (21) and a tongue (212) is formed on the other end of the cover plate (21). Two recesses (102) are defined in one end of the inner surface of the case (10) to respectively receive the tabs (214) on the cover plate (21). An elastic plate (14) is formed on the other end of the case (10), and an engaging hole (142) is defined in the elastic plate (14) at a side corresponding to the recesses (102). When the cover plate (21) is put into the opening in the case (10), the tabs (214) are received in the recesses (102) in the case (10) and the tongue (212) is engaged into the engaging hole (142) in the elastic plate (14). Accordingly, the cover plate (21) is detachably fixed in the opening of the case (10).

The connector (22) has two conducting metal pieces (23) respectively abutted against outside surfaces at two opposite sides thereof. The conducting metal pieces (23) are respectively extended into an interior of the connector (22) and electrically connected with the battery (30) or the car plug (40) via a pair of electrical wires (24), which have first ends thereof extended into the interior of the connector (22) and electrically connected with the conducting metal pieces (23), and second ends thereof respectively and electrically connected with two electrical terminals of the battery (30) or the car plug (40).

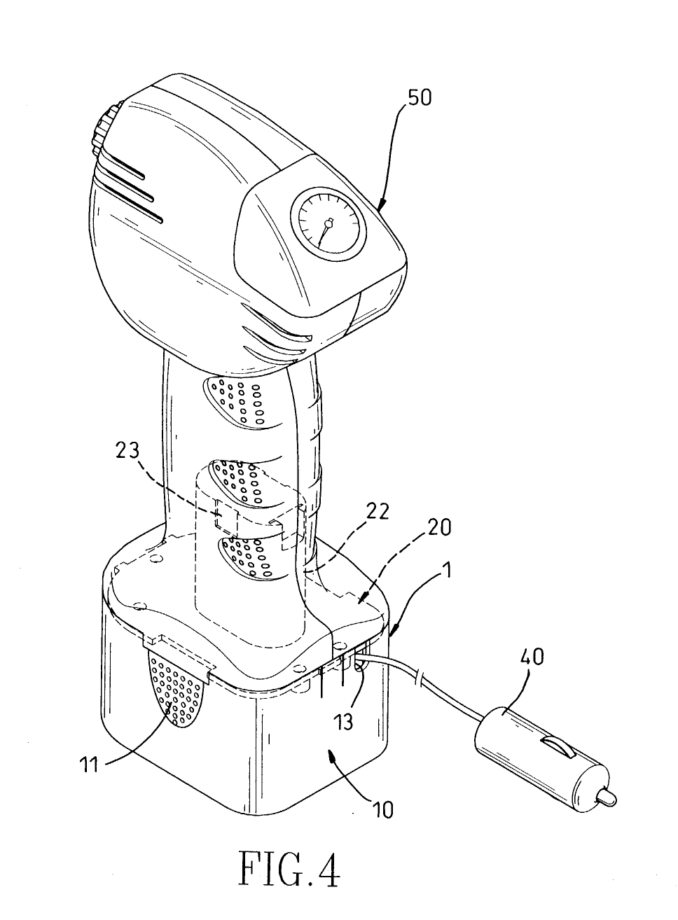

In a first application embodiment of the invention as shown in FIG. 4, the base unit (1) is cooperated with a high-pressure low-volume mechanical air pump (50), which is modularized corresponding to the base unit (1). The connector (22) is inserted into a socket defined in a lower end of the high-pressure low-volume mechanical air pump (50). The base unit (1) is detachably connected with the high-pressure low-volume mechanical air pump (50) by means of the two fasteners (11) respectively engaged into two fastening holes defined in the lower end of the high-pressure low-volume mechanical air pump (50).

For example, in the first application embodiment, the car plug (40) is provided in electrical connection with the conducting metal pieces (23) of the base unit (1). The case (10) is further defined with a cut (13) at an upper edge thereof to permit the electrical wires connected with the car plug (40) to extend therethrough. When the car plug (40) of the base unit (1) is inserted into a power supply car plug jack, the high-pressure low-volume mechanical air pump (50) is electrically connected with the power supply via the conducting metal pieces (23) and the car plug (40).

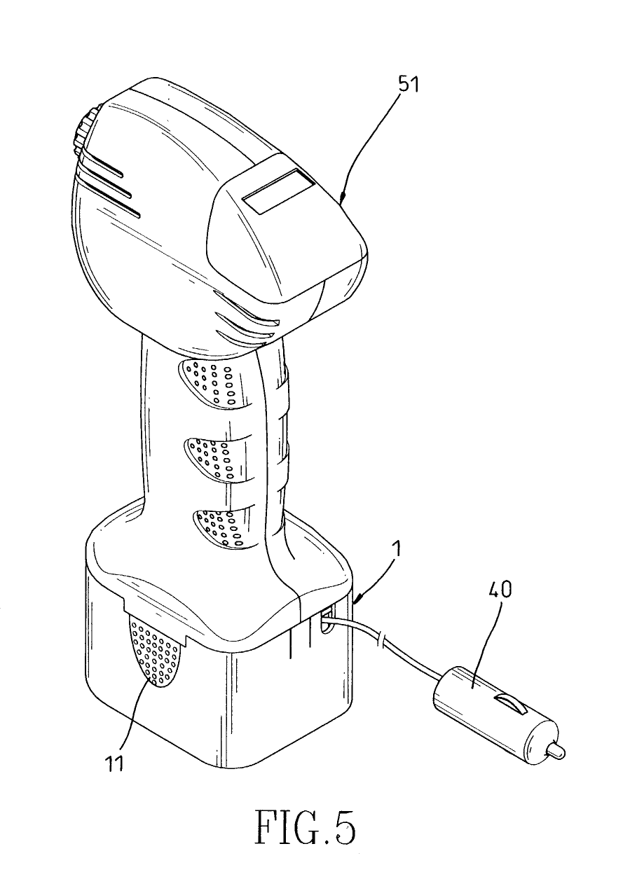

In a second application embodiment of the invention as shown in FIG. 5, the base unit (1) is cooperated with a modular air pump (51) having an LCD display.

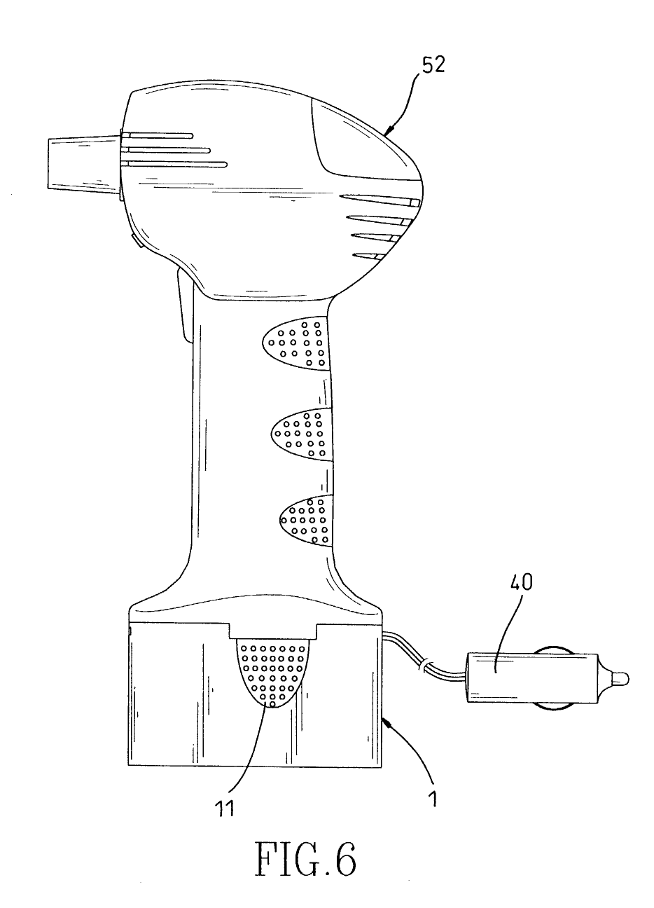

In a third application embodiment of the invention as shown in FIG. 6, the base unit (1) is cooperated with a modular low-pressure high-volume air pump (52).

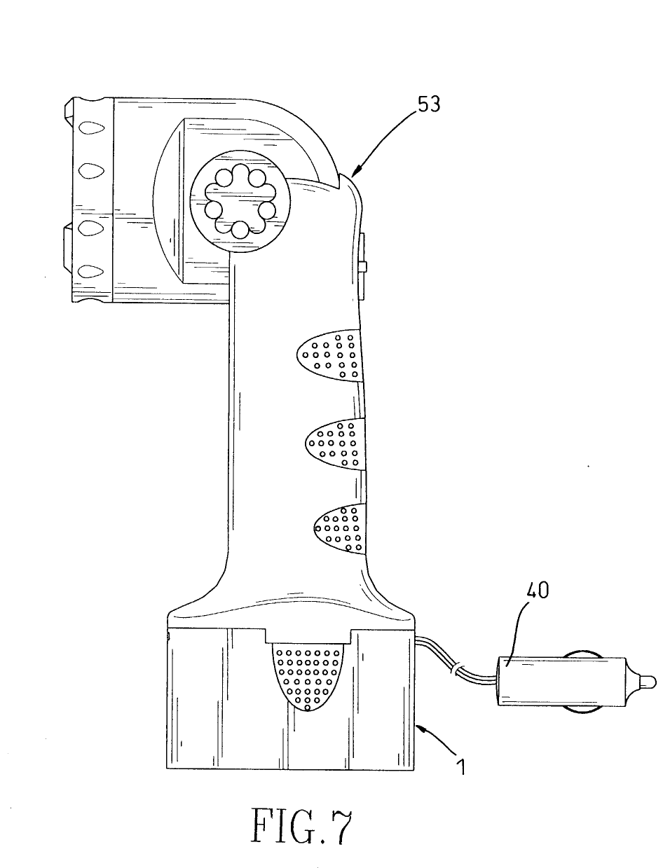

In a fourth application embodiment of the invention as shown in FIG. 7, the base unit (1) is cooperated with a modular portable lamp (53).

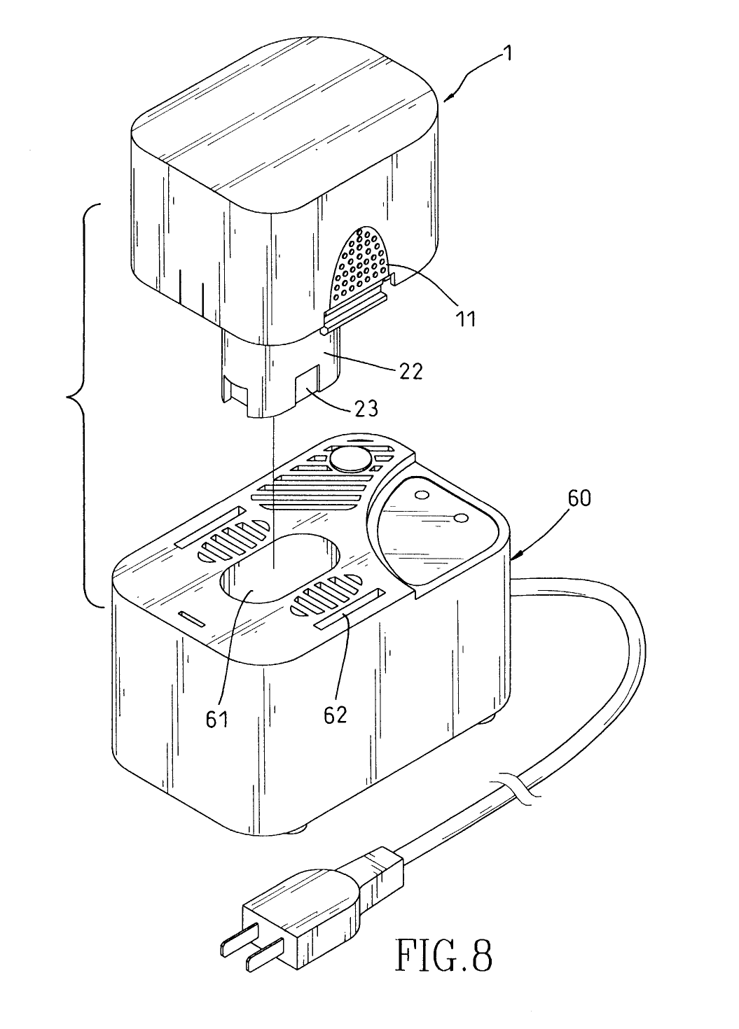

With reference to FIG. 8, a charger (60) is provided to cooperate with the rechargeable battery (30). The charger (60) has a socket (61) defined therein corresponding to the connector (22), two fastening holes (62) defined therein to correspond to the two fasteners (11), and two metal contact pieces (not shown) provided therein to correspond to the two conducting metal pieces (23), whereby the charger (60) is detachably connected to the base unit (1) by means of the fasteners (11) respectively engaging into the fastening holes (62) of the charger (60), and electrically connected with the power supply of the base unit (1) by the contact pieces electrically connecting with the conducting metal pieces (23).

The modular base unit (1) of the invention has the following advantages:

1. Because the car appliances are designed with modular structures corresponding to the modular base unit (1), each modular car appliance occupies less space than conventional integrated car appliances do, therefore the storage spaces for the modular car appliances and the base unit (1) are small.

2. As the car appliances are modularized, the production cost of the car appliances and the base unit (1) are reduced.

3. The total expenditure of buying various modular car appliances and the modular base unit for a user is economic.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A modular base unit (1) for a modular car appliance, the base unit (1) comprising:
a case (10) having a receiving space defined therein;
a connecting portion (20) having a cover plate (21) corresponding to an opening of the receiving space of the case (10), a connector (22) integrally formed on the cover plate (21), and two conducting metal pieces (23) provided at the connector (22), wherein the cover plate (21) is detachably connected with a periphery defining the opening of the receiving space, the connector (22) is adapted to correspond to a socket defined in the modular car appliance, the two conducting metal pieces (23) are extended into an interior of the connector (22), a pair of electrical wires (24) has a pair of first ends extended into the interior the connector (22) and respectively and electrically connected with the conducting metal pieces (23) and a pair of second ends adapted to respectively and electrically connect with a power supply,
wherein at least one tab is formed on one end of the cover plate and a tongue is formed on the other end of the cover plate;
a recesses is defined in one end of an inner surface of the case and corresponds to each at least one tab on the cover plate to respectively receive the corresponding tab on the cover plate; and
an elastic plate is formed on the other end of the case and has an engaging hole defined in the elastic plate at a side corresponding to the recesses to engage with the tongue on the cover plate,
whereby when the base unit (1) is detachably connected to the modular car appliance, the modular car appliance is electrically connected with the power supply via the conducting metal pieces (23) and the pair of electrical wires (24).

2. The modular base unit as claimed in claim 1, wherein the case (10) has a cut (13) defined at an upper edge thereof to permit the pair of electrical wires (24) to extend therethrough.

3. The modular base unit as claimed in claim 1, wherein two fasteners (11) are respectively provided at two opposite inner sides of the case (10) to respectively extend through the modular car appliance.

4. The modular base unit as claimed in claim 3, wherein the fasteners (11) are fixed in the case (10) by means of an elastic member (12).

5. The modular base unit as claimed in claim 1, wherein the connecting portion (20) is detachably fixed with the case (10) by means of screws.

6. The modular base unit as claimed in claim 1, wherein the connecting portion (20) is detachably fixed with the case (10) by means of lock joints.

7. The modular base unit as claimed in claim 1, wherein the two metal conducting pieces (23) are respectively abutted against two opposed sides of the connector (22).
